(19) United States
(12) Patent Application Publication
(10) Pub. No.: US 2016/0247726 A1
(43) Pub. Date: Aug. 25, 2016

(54) METHOD FOR FABRICATING A QUASI-SOI SOURCE-DRAIN MULTI-GATE DEVICE

(71) Applicant: PERKING UNIVERSITY, Beijing (CN)

(72) Inventors: Ru HUANG, Beijing (CN); Jiewen FAN, Beijing (CN); Ming LI, Beijing (CN); Yuancheng YANG, Beijing (CN); Haoran XUAN, Beijing (CN); Hanming WU, Beijing (CN); Weihai BU, Beijing (CN)

(21) Appl. No.: 15/026,396

(22) PCT Filed: Mar. 31, 2014
(86) PCT No.: PCT/CN2014/074361

§ 371 Date: Mar. 31, 2016

(30) Foreign Application Priority Data
Dec. 18, 2013 (CN) 2013 10696063.0

(51) Int. Cl. H01L 21/8238; H01L 21/3065; H01L 21/311; H01L 21/84; H01L 21/3105; H01L 21/28; H01L 21/265; H01L 29/66; H01L 29/06

(52) U.S. Cl. CPC H01L 21/823814; H01L 29/66522; H01L 29/66795; H01L 21/3065; H01L 21/31111; H01L 29/0653; H01L 21/31055; H01L 21/28264; H01L 21/28185; H01L 21/265; H01L 21/845

(57) ABSTRACT

The present invention discloses a method for fabricating a quasi SOI source-drain multi-gate device, belonging to a field of manufacturing ultra large scale integrated circuit, the method comprises in sequence the following steps of: forming a Fin strip-shaped active region on a first semiconductor substrate; forming a STI isolation layer; depositing a gate dielectric layer and a gate material layer, forming a gate stack structure; forming a doped structure of a source-drain extension region; forming a recessed source-drain structure; forming a quasi SOI source-drain isolation layer; in-situ doping an epitaxial source and drain of a second semiconductor material and performing annealing for activating; removing a dummy gate and performing a deposition of a high k metal gate again; and forming a contact and a metal interconnection.

The present application claims priority of Chinese Patent Application (No. 201310696063.0), filed on Dec. 18, 2013, which is incorporated herein by reference in its entirety.

### TECHNICAL FIELD

The invention refers to a method for fabricating a quasi SOI source-drain multi-gate device, belonging to a manufacturing technology field of an ultra large scale integrated circuit.

### BACKGROUND OF THE INVENTION

Nowadays, semiconductor manufacturing industry develops rapidly under the guidance of Moore's Law, where power consumption need be reduced as much as possible while performance and integration density of integrated circuits are improved constantly. Fabricating of an ultra-short channel device with high-performance, low-power is a focus of a future semiconductor manufacturing industry. After progressing to a 22 nm technology node, in order to overcome the problems described above, the device of a multi-gate structure becomes the hotspot of the semiconductor device nowadays due to its excellent short channel control ability and ballistic transport capacity. A 22-nanometer product of Intel has applied this structure, and exhibits the advantages of high performance and low power consumption. On the other hand, a quasi SOI source-drain device makes a leakage current be further reduced by adding an insulating isolation layer to both ends of the source and the drain, and especially for the field of ultra low power consumption devices, has great potential.

However, at present, as to the prior process for fabricating a device of quasi SOI source-drain multi-gate structure, a quasi SOI isolation layer is formed typically by performing thermal oxidation, which has a higher thermal budget, and can not be applied well to the manufacture of a large scale integration; and the prior process is limited to a Si substrate material, and can not expand well to a semiconductor substrate with a high mobility such as germanium or III-V material etc.

A method for fabricating a quasi SOI source-drain multi-gate device provided by the present invention solves at the same time these two problems described above, the fabricating process of which has better compatibility and expansibility. Furthermore, it has the characteristics that its multi-gate structure has a good gate control ability, and has a smaller leakage current and a lower power consumption in comparison with the process for fabricating the prior planar quasi SOI source-drain device.

### SUMMARY OF THE INVENTION

In order to solve the problems described above, the present invention provides a method for fabricating a quasi SOI source-drain multi-gate device, the fabrication process of this method has better compatibility and expansibility, further has the characteristics that its multi-gate structure has a good gate control ability, and has a smaller leakage current and a lower power consumption in comparison with the process for fabricating the prior planar quasi SOI source-drain device.

The method for fabricating a quasi SOI source-drain multi-gate device comprises in sequence the following steps of:
1) forming Fin strip-shaped active region on a first semiconductor material as a substrate by performing photolithography and etching;
2) forming a STI isolation layer by performing STI, wherein a backfill material of for STI is insulating dielectric, the forming of the STI isolation layer is achieved by performing chemical vapor deposition (CVD) technology, chemical mechanical polishing (CMP) and etching, and the Fin strip on the first semiconductor substrate has a height H1;
3) depositing sequentially a gate dielectric layer and a gate material layer on the substrate, forming a gate stack structure by performing photolithography and etching using gate-first process or gate-last process, wherein the gate stack structure formed by the gate-first process is a true gate, the gate stack structure formed by the gate-last process is a dummy gate;
4) forming a doped structure of a source-drain extension region by performing implantation technology, and forming a first layer of sidewall with L1 width on both sides of the gate stack structure;
5) forming a recessed source-drain structure, the recessed source-drain structure is a U-shape recessed source-drain structure, a Σ-shape recessed source-drain structure or an S-shape recessed source-drain structure;
6) depositing a quasi SOI source-drain isolation layer by performing CVD, planarizing the quasi SOI source-drain isolation layer by performing CMP, which stops on the gate material layer, then performing etching back or isotropic wet etching on the quasi SOI source-drain isolation layer to form the isotropic quasi SOI source-drain isolation layer with H5 thickness on the recessed source-drain structure, wherein a material for the quasi SOI source-drain isolation layer is different from a material for the first layer of sidewall;
7) in-situ doping an epitaxial source and drain of a second semiconductor material, and performing annealing to activate it;
8) removing the gate stack structure used as a dummy gate sacrificial layer and performing a deposition of a high k metal gate again, comprising the steps of: firstly, removing the dummy gate sacrificial layer by performing the isotropic wet etching, secondly forming a gate dielectric layer with high dielectric constant again by performing atomic layer deposition (ALD), then forming a gate material layer again by performing ALD or physical vapor deposition (PVD), and finally planarizing the gate material layer by performing CMP;
9) forming a contact and a metal interconnection.

In the method for fabricating a quasi SOI source-drain multi-gate device described above, the first semiconductor substrate is an IV or III-V semiconductor material, wherein, the IV semiconductor material is silicon, germanium or Silicon germanium, the III-V semiconductor material is gallium arsenide or indium arsenide.

Preferably, in the method for fabricating a quasi SOI source-drain multi-gate device described above, the etching is an anisotropy dry etching process, which may be performed by using a photoresist or a hard mask as a barrier layer, wherein the hard mask may be silicon oxide or silicon nitride.

After the performing of STI isolation in the step 2), it may be selected to retain a hard mask on the top on the Fin strip of the first semiconductor substrate so as to finally form a device of a double gate structure, or to remove the hard mask on the top of Fin strip of the first semiconductor material so as to finally form a device of a three-gate structure.

The step 3) further comprises the following steps: firstly, forming a layer of oxide used as the gate dielectric layer on the substrate by performing thermal oxidation, secondly forming the gate material layer by using low pressure chemical vapor deposition (LPCVD) and CMP for planarization, then forming a gate hard mask layer by using LPCVD, and finally forming the gate stack structure by performing photolithography and etching on the gate dielectric layer, the gate material layer and the gate hard mask layer; wherein: the gate dielectric may be oxide or oxynitride, of the first semiconductor substrate, formed by performing oxidation and subsequent annealing, may be a dielectric material with high dielectric constant, such as aluminum oxide, hafnium oxide or yttrium oxide, formed by performing ALD, or may also be a composition of the oxide or oxynitride of the first semiconductor substrate and the dielectric material with high dielectric constant; the gate material is polysilicon formed by performing CVD, or is a conductive material, specifically titanium nitride, tantalum nitride, titanium or aluminum, formed by performing ALD or PVD, and.

In the step 4) of the method for fabricating a quasi SOI source-drain muti-gate device, optionally, the implantation technology used in the forming of the doped structure of the source-drain extension region is conventional beam line ion implantation technology, plasma doping technology or monomolecular layer depositing and doping technology; the material of the first layer of sidewall on both sides of the gate stack is silicon nitride, which is formed by performing CVD and anisotropy dry etching.

In the step 5) of the method for fabricating a quasi SOI source-drain multi-gate device, further, the U-shape recessed source-drain structure in the step 5) is formed by performing etching, with an etching depth H1 and an etching depth H2 below a bottom of the Fin strip, so that the Fin strip on the first semiconductor substrate is etched completely; the Σ-shape recessed source-drain structure is formed based on the U-shape recessed source-drain structure by performing anisotropy wet etching, with an etching depth H3 greater than H2, on the first semiconductor substrate using TMAH etchant, the S-shape recessed source-drain structure is formed based on the U-shape recessed source-drain structure by: firstly forming a second layer of sidewall with L2 width by performing CVD and anisotropy dry etching, where a material for the second layer of sidewall is different from the material for the first layer of sidewall and has an anisotropic dry etching selectivity more than 1:5 with regard to the first semiconductor material, secondly performing isotropy dry etching, with a vertical etching depth H4 and a lateral etching width L3 greater than L2, on the first semiconductor substrate, and removing the second layer of sidewall by performing isotropy wet etching.

The U-shape recessed source-drain structure has an etching depth H2, the Σ-shape recessed source-drain structure has an etching depth H2+H3, and the S-shape recessed source-drain structure has an etching depth H2+H4. In the method for fabricating a quasi SOI source-drain multi-gate device, the etching depth H5 of the U-shape recessed source-drain structure is less than the etching depth of the U-shape recessed source-drain structure, the etching depth of the Σ-shape recessed source-drain structure or the etching depth of the S-shape recessed source-drain structure, so that a window is reserved in advance in the recessed source-drain extension region so as to form the contact for the source-drain by subsequent epitaxial growing process.

In the step 6) of the method for fabricating a quasi SOI source-drain multi-gate device, the material for the quasi SOI source-drain isolation layer is different from the material for the first layer of sidewall, aluminum oxide with better thermal conductivity or silicon oxide may be selected.

In the method for fabricating a quasi SOI source-drain multi-gate device, optionally, the material of the epitaxial second semiconductor which is in-situ doped in step 7) is different from or is the same as the material of the first semiconductor, the source and drain of CMOS is formed by in-situ doping the material of the epitaxial second semiconductor, wherein P-type doping is performed on PMOS or N-type doping is performed on NMOS; manner of the annealing for activating used in the step 7) is selected from one or more of the following manners: furnace annealing, rapid thermal annealing, sparkling annealing and laser annealing.

Using Si substrate as the first semiconductor substrate is taken as an example, the technical solution of the method for fabricating a quasi SOI source-drain multi-gate device according to the present invention comprises the following steps:
I. forming Fin strip-shaped active region on the Si substrate by performing photolithography and etching
   a) forming a first layer of silicon oxide on the Si substrate by performing thermal oxidation, as a buffer layer for the silicon nitride;
   b) depositing a first layer of silicon nitride, as a stop layer for CMP, on the first layer of silicon oxide by performing LPCVD;
   c) forming a hard mask layer for silicon Fin strip by performing photolithography and anisotropy dry etching on the first layer of silicon nitride and the first layer of silicon oxide;
   d) forming the silicon Fin strip by performing anisotropic dry etching on the silicon substrate.
II. forming a STI isolation layer by performing STI
   a) depositing a second layer of silicon oxide as a backfill material for trench of STI by performing high density plasma chemical vapor depositing (HDPCVD).
   b) planarizing the second layer of silicon oxide by performing CMP, which stops on the first layer of silicon nitride;
   c) performing anisotropic dry etching on the second layer of silicon oxide, the Fin strip on the silicon substrate after etching has a height H1;
   d) removing the first layer of silicon nitride and the first layer of silicon oxide by performing isotropic wet etching.
III. depositing a gate dielectric layer and a gate material layer on the silicon substrate to form a gate stack structure as a dummy gate sacrificial layer by a gate-last process
   a) forming a third layer of silicon oxide, as a dummy gate dielectric layer, on the silicon substrate by performing thermal oxidation;
   b) depositing a first layer of polysilicon by performing LPCVD, as a dummy gate material layer;
   c) planarizing the first layer of polysilicon by performing CMP;
   d) depositing a second layer of silicon nitride by performing LPCVD, as a gate hard mask layer;
   e) forming the gate stack structure by performing photolithography and anisotropic dry etching on the second layer of silicon nitride, the first layer of polysilicon and the third layer of silicon oxide.
IV. forming a doped structure of a source-drain extension region by the implantation technology, and forming a first layer of sidewall with width L1 on both sides of the gate stack layer
   a) forming the doped structure by performing implantation on the source-drain extension region;
   b) depositing a third layer of silicon nitride, as a material for the first layer of sidewall, by performing LPCVD, wherein a deposited thickness is L1;
   c) forming the first layer of sidewall on both sides of the gate stack structure by performing anisotropic etching on the third layer of silicon nitride to remove the silicon nitride on both sides of Fin strip on the silicon substrate by using over-etching, the width of the first layer of sidewall is L1.
V. forming a recessed source-drain structure, which may be a U-shape recessed source-drain structure, a Σ-shape recessed source-drain structure or an S-shape recessed source-drain structure, wherein a window is reserved in advance in the recessed source-drain extension region by controlling an etching depth of the recessed source-drain structure
   a) performing anisotropic dry etching, with an etching depth H1 and an etching depth H2 below a bottom of the Fin strip, on the silicon substrate so that the Fin strip on the silicon substrate is etched completely to form the U-shape recessed source-drain structure with an etching depth H2;
   b) based on the U-shape recessed source-drain structure, by performing the wet etching with an etching depth H3, the Σ-shape recessed source-drain structure is formed when H3 is more than H2, wherein the Σ-shape recessed source-drain structure has an etching depth of a sum of H2 and H3;
   c) or based on the U-shape recessed source-drain structure, firstly depositing a fourth layer of silicon oxide, as a material for a second layer of sidewall, by performing LPCVD with a deposited thickness L2; secondly forming the second layer of sidewall with width L2 by performing anisotropic dry etching on the fourth layer of silicon oxide, wherein the second layer of sidewall aims to protect the source-drain extension region from removing in a subsequent isotropic dry etching; then by performing isotropic dry etching, with a vertical etching depth H4 and a lateral etching width L3, on the silicon substrate, the S-shape recessed source-drain structure is formed when L3 is more than L2, and the fourth layer of silicon oxide (the second layer of sidewall) is removed by performing isotropic wet etching; the S-shape recessed source-drain structure has an etching depth of a sum of H2 and H4.
VI. forming a quasi SOI source-drain isolation layer on the recessed source-drain structure
   a) depositing a first layer of aluminum oxide by performing LPCVD, as a material for the quasi SOI source-drain isolation layer;
   b) planarizing the first layer of aluminum oxide by performing CMP, which stops on the second layer of silicon nitride (the gate hard mask layer);
   c) etching the first layer of aluminum oxide by performing anisotropic dry etching, which stops on the second layer of silicon oxide (STI silicon oxide);
   d) forming the quasi SOI source-drain isolation layer with a thickness H5 by performing isotropic wet etching on the first layer of aluminum oxide, wherein the quasi SOI source-drain isolation layer formed on the U-shape recessed source-drain structure satisfies that H5 is less than H2, the quasi SOI source-drain isolation layer formed on the Σ-shape recessed source-drain structure satisfies that H5 is less than the sum of H2 and H3, the quasi SOI source-drain isolation layer formed on the S-shape recessed source-drain structure satisfies that H5 is less than the sum of H2 and H4.
VII. through the epitaxial window for the recessed source drain extension region which is reserved in advance when the recessed source-drain structure is formed, in-situ doping an epitaxial P type germanium silicon source-drain and performing activating by laser annealing and rapid thermal annealing
VIII. removing the gate stack structure used as the dummy gate sacrificial layer, and performing a deposition of the high k metal gate again
   a) depositing a fifth layer of silicon oxide as a 0^{th} isolation dielectric layer by performing LPCVD;
   b) planarizing the fifth layer of silicon oxide, the second layer of silicon nitride and the third layer of silicon nitride by performing CMP, which stops on the first layer of polysilicon (the dummy gate material layer);
   c) removing the first layer of polysilicon (the dummy gate material layer) by performing isotropic wet etching;
   d) removing the third layer of silicon oxide (the dummy gate dielectric layer) by performing isotropic wet etching;
   e) forming an interface layer by performing in-situ vapor oxidation;
   f) depositing a first layer of dielectric with high dielectric constant (the true gate dielectric layer) by performing ALD;
   g) depositing a first layer of metal work function (a true gate work function adjusting layer) by performing ALD;
   h) depositing the first layer of metal gate (the true gate material layer) by performing PVD;
   i) planarizing the first layer of metal gate by CMP, which stops on the fifth layer of silicon oxide.
IX. forming a contact and a metal interconnection.

The present invention has the technical effects as follows:

The method for fabricating the quasi SOI source-drain multi-gate device according to the present invention has the characteristics that its multi-gate structure has a good gate control ability, and has a smaller leakage current and a lower power consumption in comparison with the process for fabricating a prior planar quasi SOI source-drain multi-gate device. At the same time, the fabrication process according to the present invention has a smaller thermal budget and overcomes the shortcoming and limitation of the prior fabrication process of quasi SOI source-drain multi-gate device that a thermal budget is higher and only a silicon material can be used as a substrate; and the fabrication process can be compatible with the process of the traditional CMOS, can be applied to the semiconductor materials such as germanium, germanium silicon and III-V groups in addition to silicon, and can benefit being applied to the manufacturing of large scale integrated circuit.

### BRIEF DESCRIPTION OF THE DRAWINGS

FIGS. 1 to 22 are schematic views illustrating structures of a device formed by the specific implementation process for fabricating the quasi SOI source-drain silicon multi-gate device according to the present invention, wherein:

FIG. 1 is a schematic view illustrating a structure of the device after forming silicon Fin strip.

FIG. 2 is a schematic view illustrating a structure of the device after forming a STI isolation layer by performing STI.

FIG. 3 is a schematic view illustrating a structure of the device after forming a gate stack structure with a gate hard mask.

FIG. 4 is a schematic view illustrating a structure of the device after forming a first layer of sidewall on both sides of the gate stack structure.

FIG. 5 is a schematic view illustrating a structure of the device after forming a U-shape recessed source-drain structure.

FIG. 6 is a cross-section view taken along cutting line AA of FIG. 5.

FIG. 7 is a schematic view illustrating a structure of the device after forming a Σ-shape recessed source-drain structure.

FIG. 8 is a cross-section view taken along cutting line AA of FIG. 7.

FIG. 9 is a schematic view illustrating a structure of the device after forming a second layer of sidewall during forming an S-shape recessed source-drain structure.

FIG. 10 is a cross-section view taken along cutting line AA of FIG. 9.

FIG. 11 is a schematic view illustrating a structure of the device after removing the second layer of sidewall during forming the S-shape recessed source-drain structure.

FIG. 12 is a cross-section view taken along cutting line AA of FIG. 11.

FIG. 13 is a schematic view illustrating a structure of the device after forming a quasi SOI source-drain isolation layer on the U-shape recessed source-drain structure.

FIG. 14 is a cross-section view taken along cutting line AA of FIG. 13.

FIG. 15 is a schematic view illustrating a structure of the device after forming the quasi SOI source-drain isolation layer on the Σ-shape recessed source-drain structure.

FIG. 16 is a cross-section view taken along cutting line AA of FIG. 15.

FIG. 17 is a schematic view illustrating a structure of the device after forming the quasi SOI source-drain isolation layer on the S-shape recessed source-drain structure.

FIG. 18 is a cross-section view taken along cutting line AA of FIG. 17.

FIG. 19 is a schematic view illustrating a structure of the device after in-situ doping an epitaxial source-drain and performing activating by annealing.

FIG. 20 is a schematic view illustrating a structure of the device after removing a dummy gate in the gate-last process.

FIG. 21 is a schematic view illustrating a structure of the device after forming a high k metal gate again.

FIG. 22 is a schematic view illustrating a structure of the device after forming a contact and a metal interconnection.

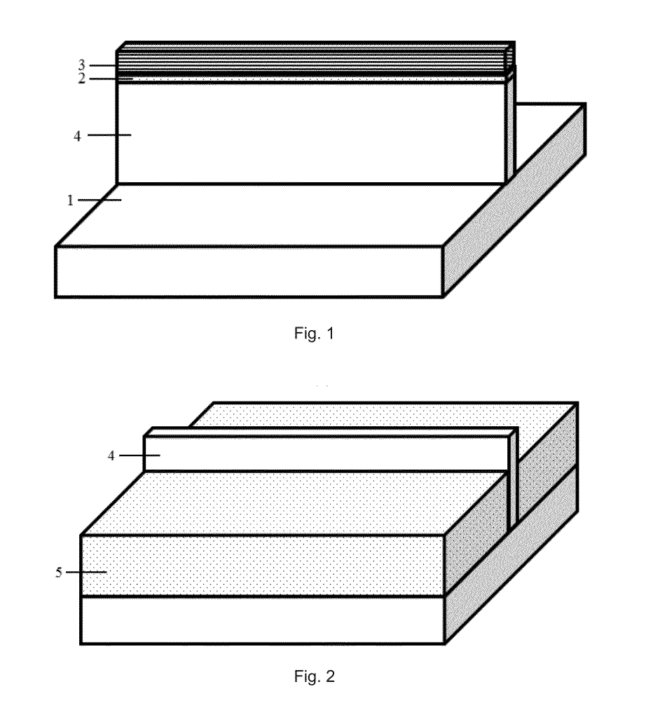

In FIG. 1 to FIG. 22:

1—a silicon substrate; 2—a first layer of silicon oxide (a buffer layer for silicon nitride); 3—a first layer of silicon nitride (a stop layer for CMP); 4—silicon Fin strip; 5—a second layer of silicon oxide (back fill material for trench of STI); 6—a third layer of silicon oxide (a dummy gate dielectric layer); 7—a first layer of polysilicon (a dummy gate material layer); 8—a second layer of silicon nitride (a gate hard mask layer); 9—a third layer of silicon nitride (a first layer of sidewall); 10—U-shape recessed source-drain structure; 11—Σ-shape recessed source-drain structure; 12—a fourth layer of silicon oxide (a second layer of sidewall); 13—S-shape recessed source-drain structure; 14—a first layer of aluminum oxide (a recessed source-drain isolation material); 15—epitaxial source and drain; 16—a fifth layer of silicon oxide (a 0^{th} isolation dielectric layer); 17—aluminum.

FIG. 23 is an illustration of the used materials.

### DETAILED DESCRIPTION OF THE EMBODIMENTS

Hereinafter, the present invention is described in detail with reference to the specific embodiments in conjunction with the accompanying drawings. Specifically, a process solution for fabricating a quasi SOI source-drain multi-gate device proposed by the present invention is provided, which does not limit the scope of the invention in any way.

The specific implementation steps for fabricating a quasi SOI source-drain multi-gate device on a silicon substrate by a gate-last process are provided as follows:

1. a first layer of silicon oxide 2 of 100 Å, is formed on a silicon substrate 1 by thermal oxidation, as a buffer layer for silicon nitride;

2. a first layer of silicon nitride 3 of 500 Å, is deposited on the first layer of silicon oxide by performing LPCVD, as a stop layer for Chemical Mechanical Polishing (CMP);

3. a hard mask layer for silicon Fin strip is formed by performing photolithography and anisotropic dry etching on the first layer of silicon nitride 3 of 500 Å and the first layer of silicon oxide 2 of 100 Å;

4. the silicon substrate of 3000 Å is etched by performing anisotropic dry etching to form the silicon Fin strip 4, and the silicon Fin strip after etching has a width 10 nm, as shown in FIG. 1;

5. a second layer of silicon oxide 5 of 8000 Å, is deposited by performing HDPCVD, as a back fill material for a trench of Shallow Trench Isolation (STI);

6. the second layer of silicon oxide 5 is planarized by performing CMP, which stops on the first layer silicon nitride 3;

7. the second layer of silicon oxide 5 of 900 Å is etched by performing the anisotropic dry etching, the silicon Fin strip after etching has a height H1=30 nm;

8. the first layer of silicon nitride 3 of 500 Å is removed by performing an isotropic wet etching using concentrated phosphoric acid solution at 170° C., and the first layer of silicon oxide 2 of 100 Å is removed by performing the isotropic wet etching using hydrofluoric acid solution, as shown in FIG. 2;

9. a third layer of silicon oxide 6 of 50 Å, is formed on the silicon substrate by performing the thermal oxidation, as a dummy gate dielectric layer;

10. a first layer of polysilicon 7 of 2000 Å, is deposited by performing LPCVD, as a dummy gate material layer;

11. the first layer of polysilicon 7 is planarized by performing CMP to have 1000 Å;

12. a second layer of silicon nitride 8 of 500 Å, is deposited by performing LPCVD, as agate hard mask layer;

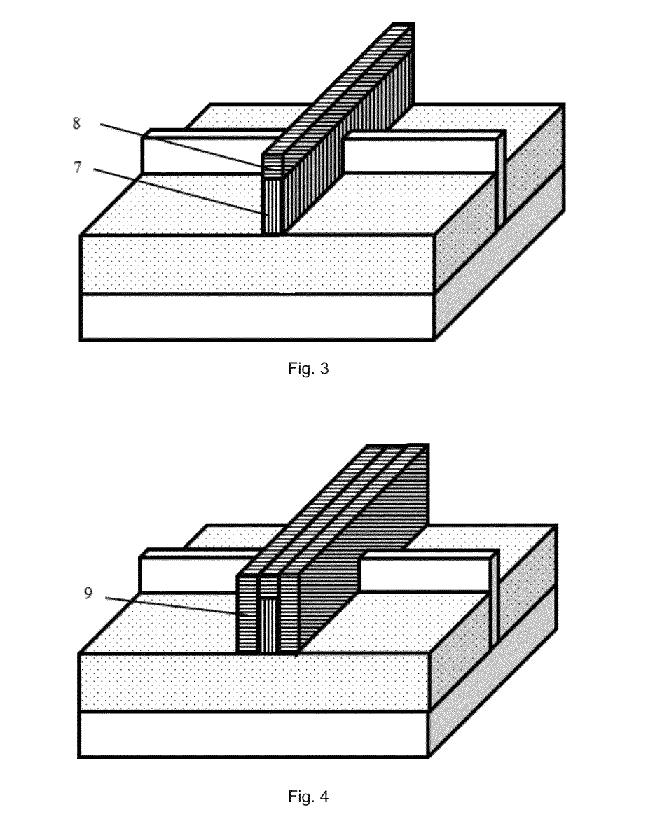

13. the second layer of silicon nitride 8 of 500 Å, the first layer of polysilicon 6 of 1000 Å and the third layer of silicon oxide 6 of 50 Å are etched by performing photolithography and anisotropic dry etching to form a gate stack structure with a gate length 30 nm, as shown in FIG. 3.

14. ion As is implanted into a source-drain extension region by performing ion implantation with a dose of 1e15cm-2, an energy of 5 keV and an angel of 10°, and is implanted in four times to achieve a doping;

15. a third layer of silicon nitride 9 is deposited by LPCVD, as a material for a first layer of sidewall, the deposited thickness is L1=300 Å;

16. the third layer of silicon nitride 9 of 600 Å is etched by performing anisotropic dry etching and the third layer of silicon nitride 9 on both sides of silicon Fin strip is removed by using over-etching, so as to form the first layer of sidewall on both sides of the gate stack structure with a width 300 Å, as shown in FIG. 4;

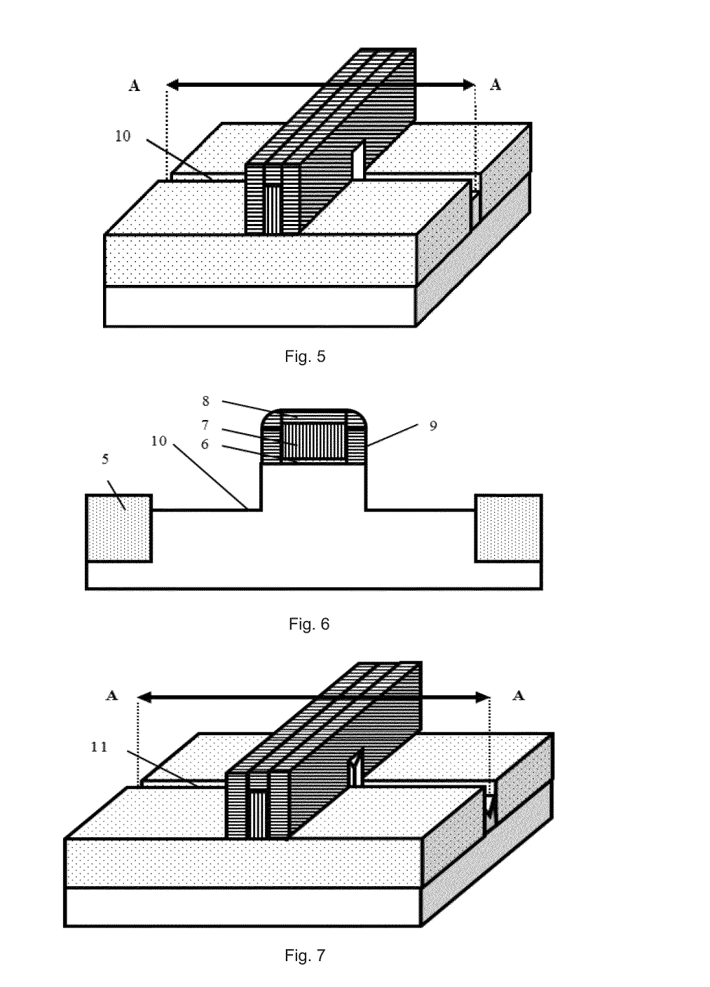

17. the silicon substrate is etched by performing the anisotropic dry etching, wherein a total etching depth is H1+H2=600 Å, the silicon Fin strip is etched completely with an etching depth H1=30 nm, and an etching depth below a bottom of the silicon Fin strip is H2=300 Å. and thereby a U-shape recessed source-drain structure 10 is formed, as shown in FIG. 5, where FIG. 6 is a cross-section view taken along cutting line AA of FIG. 5;

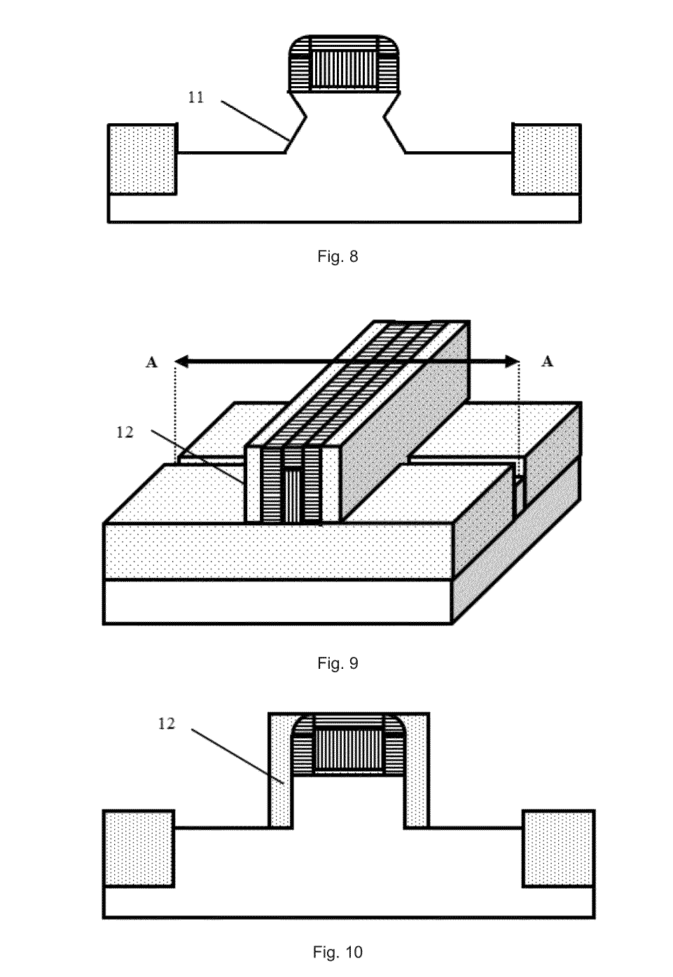

18. the silicon substrate is etched by performing the anisotropic wet etching, the etching depth being H3=500 Å, meeting H3>H2, and thereby a Σ-shape recessed source-drain structure 11 is formed, as shown in FIG. 7, where FIG. 8 is a cross-section view taken along cutting line AA of FIG. 7;

19. a fourth layer of silicon oxide 12 of 300 Å, is deposited by performing LPCVD, as a second layer of sidewall;

20. a fourth layer of silicon oxide 12 of 600 Å is etched by performing the anisotropic dry etching to form the second layer of sidewall with a width 300 Å for protecting the source-drain extension region from removing in the subsequent isotropic dry etching process, as shown in FIG. 9, where FIG. 10 is a cross-section view taken along cutting line AA of FIG. 9;

21. the silicon substrate is etched by performing the isotropic dry etching, a vertical etching depth being H4=500 Å, a lateral etching width being L2=800 Å, meeting L2>L1, and thereby a S-shape recessed source-drain structure 13 is formed;

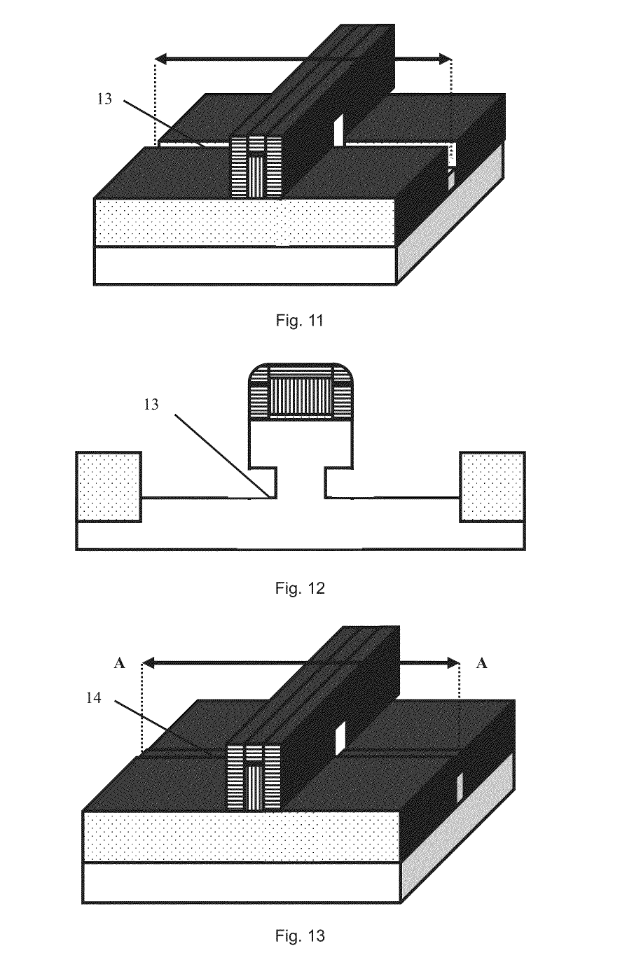

22. the fourth layer silicon oxide 12 of 300 Å (the second sidewall) is removed by performing the isotropic wet etching, as shown in FIG. 11, where FIG. 12 is a cross-section view taken along cutting line AA of FIG. 11;

23. a first layer of aluminum oxide 14, is deposited by performing LPCVD, as a material for a quasi SOI source-drain isolation layer;

24. the first layer of aluminum oxide 14 is planarized by performing CMP, which stops on the second layer of silicon nitride 8 (the gate hard mask layer);

25. the first layer of aluminum oxide 14 of 1250 Å is etched by performing the anisotropic dry etching, which stops on the second layer of silicon oxide 5, that is, on the STI silicon oxide;

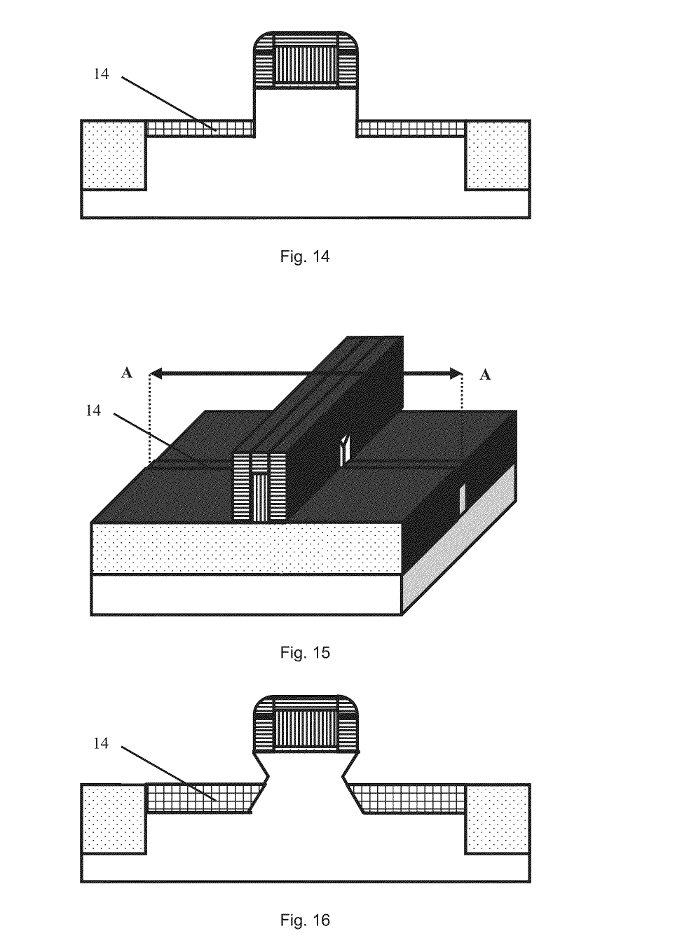

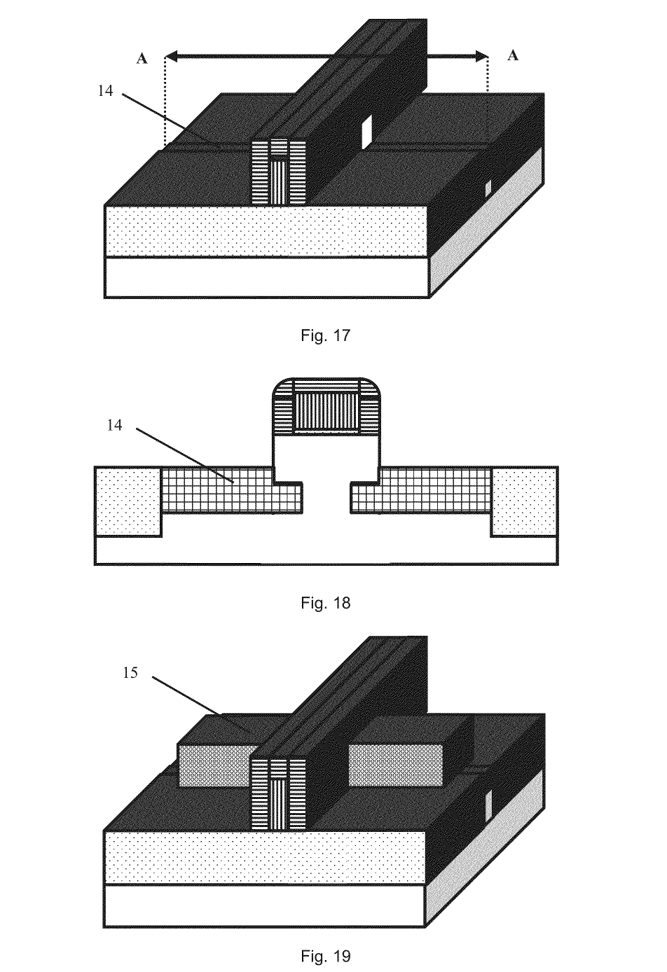

26. the first layer of aluminum oxide 14 of 200 Å is etched by performing the isotropic wet etching using hydrochloric acid, the etching depth being less than H2, the quasi SOI source-drain isolation layer is formed, the thickness of the isolation layer being H5, meeting H5<H2 for the U-shape recessed source-drain structure, as shown in FIG. 13, where FIG. 14 is a cross-section view taken along the cutting line of FIG. 13; meeting H5<H2+H3 for the Σ-shape recessed source-drain structure, as shown in FIG. 15, where FIG. 16 is a cross-section view taken along cutting line AA of FIG. 15; meeting H5<H2+H4 for the S-shape recessed source-drain structure, as shown in FIG. 17, where FIG. 18 is a cross-section view taken along cutting line AA of FIG. 17;

27. an epitaxial P-type germanium silicon source and drain 15 of 500 Å is formed by performing in-situ doping through an epitaxial window for the source-drain extension region reserved in advance;

28. laser annealing is performed for a period of 1 ms at a temperature of 1200° C.

29. rapid thermal annealing is performed with an initial temperature and a final temperature both of 400° C., a peak temperature of 900° C., an ascending temperature of 200° C./s and a descending temperature of 150° C./s, as shown in FIG. 19.

When the gate-last process is used, the previous dummy gate need be removed, and the high k metal gate need be deposited again, comprising the steps of:

30. a fifth layer of silicon oxide 16 of 5000 Å is deposited by performing LPCVD, as a 0^{th} isolation dielectric layer;

31. the fifth layer of silicon oxide 16, the second layer of silicon nitride 8 and the third layer of silicon nitride 9 are planarized by performing CMP, which stops on the first layer of polysilicon 7 (the gate material layer).

32. the first layer of polysilicon 7 of 1000 Å, i.e., the dummy gate material layer is removed by performing the isotropic wet etching using TMAH solution;

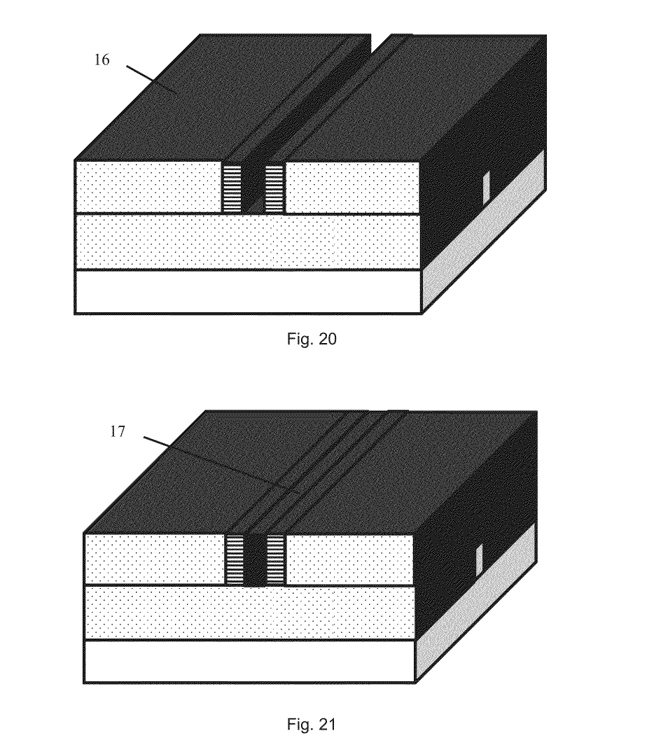

33. the third layer of silicon oxide 6 of 50 Å, i.e., the dummy gate dielectric layer, is removed by performing the isotropic wet etching using hydrofluoric acid solution as shown in FIG. 20.

34. a silicon oxide interface layer of 10 Å is formed by performing an in situ vapor oxidation;

35. a first layer of high dielectric constant dielectric, i.e., hafnium oxide of 20 Å, is deposited by performing ALD, which is a true gate dielectric layer;

36. a first layer of metal work function, i.e., titanium nitride of 50 Å, is deposited by performing ALD, which is a true gate work function adjusting layer;

37. a first layer of metal gate, i.e., aluminum 17 of 2000 Å, is deposited by performing PVD, which is a true gate material layer;

38. the first layer metal gate 17 is planarized by performing CMP, which stops on the fifth layer of silicon oxide 16, as shown in FIG. 21;

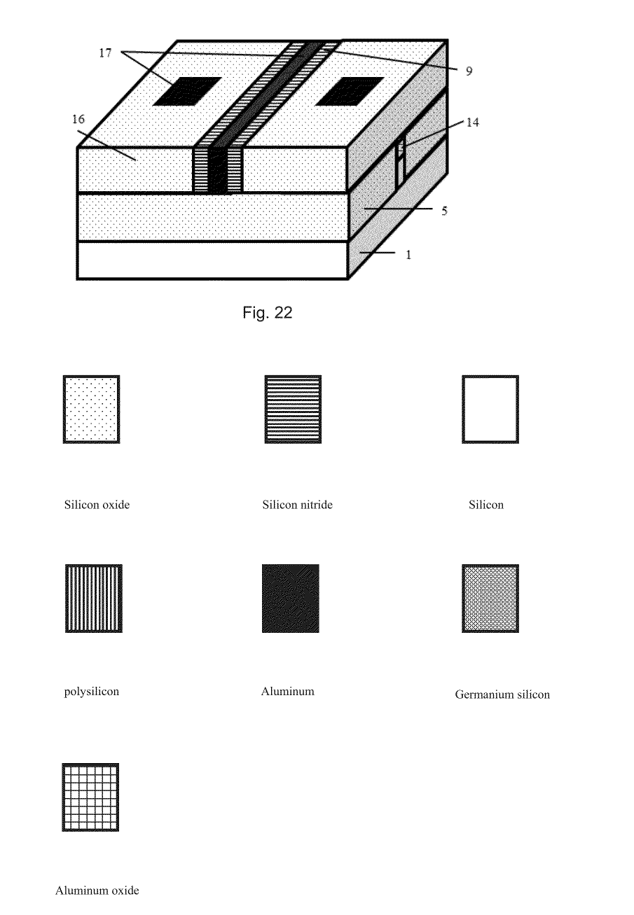

39. finally, a contact and a metal interconnection are formed, as shown in FIG. 22.

The embodiments described above do not be used to limit the present invention, various changes and modification can be made by a person skilled in the art without departing from the spirit and scope of the present invention, and the protection scope of the present invention is defined by the claims.

1. A method for fabricating a quasi SOI source-drain multi-gate device, comprising in sequence the following steps of:
(1) forming Fin strip-shaped active region on a first semiconductor material as a substrate by performing photolithography and etching;
(2) forming a STI isolation layer by performing STI, wherein a backfill material for STI is insulating dielectric, the forming of the STI isolation layer is achieved by performing chemical vapor deposition (CVD) technology, chemical mechanical polishing technology and etching, and the Fin strip on the substrate has a height H1;
(3) depositing sequentially a gate dielectric layer and a gate material layer on the substrate, and forming a gate stack structure by performing photolithography and etching using a gate-first process or a gate-last process, wherein the gate stack structure formed by the gate-first process is a true gate, the gate stack structure formed by the gate-last process is a dummy gate;
(4) forming a doped structure of a source-drain extension region by implantation technology, and forming a first layer of sidewall with width L1 on both sides of the gate stack structure;
(5) forming a U-shape recessed source-drain structures, a Σ-shape recessed source-drain structure or a S-shape recessed source-drain structure;
(6) depositing a quasi SOI source-drain isolation layer by performing CVD, planarizing the quasi SOI source-drain isolation layer by performing CMP, which stops on the gate material layer, then performing etching back or isotropic wet etching on the quasi SOI source-drain isolation layer to form the quasi SOI source-drain isolation layer with thickness H5 on the recessed source-drain structure, wherein a material for the quasi SOI source-drain isolation layer is different from a material for a first layer of sidewall;
(7) in-situ doping an epitaxial second semiconductor material to form the source and drain, and performing annealing to activate the source and drain;
(8) if the gate-first process is used in the step (3), directly proceeding to step (9); if the gate-last process is used in the step (3), removing the gate stack structure as a dummy gate sacrificial layer and performing a deposition of a high k metal gate again, specifically comprising steps of: firstly, removing the dummy gate sacrificial layer by performing the isotropic wet etching, secondly forming a gate dielectric layer with high dielectric constant again by performing atomic layer deposition, then forming a gate material layer again by performing atomic layer deposition or physical vapor deposition, and finally planarizing the gate material layer by performing CMP;
(9) forming a contact and a metal interconnection.

2. The method for fabricating a quasi SOI source-drain multi-gate device according to claim 1, wherein the first semiconductor material is an IV or III-V semiconductor material.

3. The method for fabricating a quasi SOI source-drain multi-gate device according to claim 1, wherein the etching is an anisotropy dry etching process, which is performed by using a photoresist or a hard mask as a barrier layer, wherein the hard mask is silicon oxide or silicon nitride.

4. The method for fabricating a quasi SOI source-drain multi-gate device according to claim 1, wherein, after the performing of STI isolation in the step (2), retaining a hard mask on the top of the Fin strip on the substrate so as to finally form a device of a double gate structure; or removing the hard mask on the top of Fin strip on the substrate so as to finally form device of a three-gate structure.

5. The method for fabricating a quasi SOI source-drain multi-gate device according to claim 1, wherein, the step (3) further comprises the following steps of: firstly, forming a layer of oxide as the gate dielectric layer on the substrate by thermal oxidation, secondly forming the gate material layer by using low pressure chemical vapor deposition and chemical mechanical polishing technology for planarization, then forming a gate hard mask layer by using low pressure chemical vapor deposition, and finally forming the gate stack structure by performing photolithography and etching on the gate dielectric layer, the gate material layer and the gate hard mask layer; wherein: the gate dielectric is oxide or oxynitride, of the first semiconductor material for the substrate, formed by oxidation and subsequent annealing, is a dielectric material with high dielectric constant formed by atom layer deposition, or is a composition of the oxide or oxynitride of the material for the substrate and the dielectric material with high dielectric constant; the gate material is polysilicon formed by CVD, or is a conductive material formed by atom layer deposition or physical vapor deposition, the conductive material is titanium nitride, tantalum nitride, titanium or aluminum.

6. The method for fabricating a quasi SOI source-drain multi-gate device according to claim 1, wherein, the implantation technology used in the forming of the doped structure of the source-drain extension region in the step (4) is beam line ion implantation technology, plasma doping technology or monomolecular layer deposition doping technology; a material for the first layer of sidewall on both sides of the gate stack is silicon nitride, and is formed by chemical vapor deposition and anisotropy dry etching.

7. The method for fabricating a quasi SOI source-drain multi-gate device according to claim 1, wherein, the U-shape recessed source-drain structure in the step (5) is formed by performing etching, with an etching depth H1 and an etching depth H2 below a bottom of the Fin strip, so that the Fin strip on the substrate is etched completely; the Σ-shape recessed source-drain structure is formed based on the U-shape recessed source-drain structure by performing anisotropy wet etching, with an etching depth H3 greater than H2, on the substrate using TMAH etchant; the S-shape recessed source-drain structure is formed based on the U-shape recessed source-drain structure by: firstly forming a second layer of sidewall with width L2 by performing chemical vapor deposition and anisotropy dry etching, where a material for the second layer of sidewall is different from the material for the first layer of sidewall and has an anisotropic dry etching selectivity more than 1:5 with regard to the first semiconductor material, secondly performing isotropy dry etching, with a vertical etching depth H4 and a lateral etching width L3 greater than L2, on the substrate, and removing the second layer of sidewall by performing isotropy wet etching.

8. The method for fabricating a quasi SOI source-drain multi-gate device according to claim 1, wherein the U-shape recessed source-drain structure has an etching depth H2, the Σ-shape recessed source-drain structure has an etching depth H2+H3, and the S-shape recessed source-drain structure has an etching depth H2+H4, where the etching depth H5 of the U-shape recessed source-drain structure is less than the etching depth of the recessed source-drain structure, so that a window is reserved in advance in the recessed source-drain extension region.

9. The method for fabricating a quasi SOI source-drain multi-gate device according to claim 1, wherein the material for the quasi SOI source-drain isolation layer in step (6) is silicon oxide or aluminum oxide.

10. The method for fabricating a quasi SOI source-drain multi-gate device according to claim 1, wherein the second semiconductor material in step (7) is different from or is the same as the first semiconductor material in the step (1), the source and drain of CMOS is formed by in situ doping the epitaxial second semiconductor material, wherein P-type doping is performed on PMOS or N-type doping is performed on NMOS; manner of the annealing for activating used in the step (7) is selected from one or more of the following manners: furnace annealing, rapid thermal annealing, sparkling annealing and laser annealing.

11. The method for fabricating a quasi SOI source-drain multi-gate device according to claim 7, wherein the U-shape recessed source-drain structure has an etching depth H2, the Σ-shape recessed source-drain structure has an etching depth H2+H3, and the S-shape recessed source-drain structure has an etching depth H2+H4, where the etching depth H5 of the U-shape recessed source-drain structure is less than the etching depth of the recessed source-drain structure, so that a window is reserved in advance in the recessed source-drain extension region.
